(19) United States
(12) Patent Application Publication
(10) Pub. No.: US 2013/0323477 A1
(43) Pub. Date: Dec. 5, 2013

(54) METHOD FOR MANUFACTURING A DECORATED GLASS SHEET

(71) Applicants: Jean-Michel Depauw, Jumet (BE); Nerio Lucca, Jumet (BE); Bruno Symoens, Jumet (BE)

(72) Inventors: Jean-Michel Depauw, Jumet (BE); Nerio Lucca, Jumet (BE); Bruno Symoens, Jumet (BE)

(73) Assignee: AGC Glass Europe, Bruxelles (Watermael-Boitsfort) (BE)

(21) Appl. No.: 13/985,730

(22) PCT Filed: Feb. 14, 2012
(86) PCT No.: PCT/EP2012/052514

§ 371 Date: Aug. 15, 2013

(30) Foreign Application Priority Data
Feb. 15, 2011 (BE) BE 2011/0098

(51) Int. Cl. C03C 17/36; C23C 14/35; C03C 17/34

(52) U.S. Cl. CPC C03C 17/3607; C03C 17/3417; C23C 14/35
USPC 428/201; 204/192.12; 204/192.15

(57) ABSTRACT

The invention relates to a method for manufacturing a decorated glass sheet covered with a functional coating, including the sequential steps of applying at least one decorative pattern onto at least a portion of a surface of the glass sheet by printing, drying the printed decorative pattern, and depositing the functional coating such that it at least partially covers said decorative pattern, by magnetron cathode sputtering. The invention further relates to the use of the resulting covered decorated glass sheet as a facing element.

### 1. FIELD OF THE INVENTION

The field of the invention is that of processes for manufacturing decorated glass sheets covered with a functional coating that provides low-emissivity, solar protection, protective or electrical conductivity properties.

More specifically, the invention relates to a method for to manufacturing a decorated glass sheet covered with a functional coating that provides low-emissivity or solar protection properties, wherein the functional coating is deposited on the face of the glass sheet provided with the decorative pattern and at least partially covers said decorative pattern.

### 2. PRIOR ART SOLUTIONS

Applications using a glass sheet decorated with a pattern are such that said pattern is generally seen through the thickness of the glass sheet. When the decorated glass sheet is intended to be used as an element of a building facade, it is essential that the glass sheet has an energy-saving function in addition to its decorative function. The term “energy-saving” is understood to mean that the decorated glass sheet also enables the reduction of heat exchanges on either side thereof. Heat exchanges through the decorated glass sheet are reduced by depositing a low-emissivity or solar shield coating. Moreover, the functional coating must not modify the colour of the pattern by its position in any way; in other words, the colour of the pattern viewed through the glass sheet must not be influenced by the functional coating.

The low-emissivity or solar shield coating can be arranged between, the glass sheet and the decorative pattern or on top of said decorative pattern. However, it has been observed, as outlined in document WO2006/061541 A2, that positioning the functional coating on top of the pattern has the advantage of preventing denaturation of the pattern, but also of being able to reduce the awareness of any faults present in said coating, thus resulting in a better aesthetic appearance.

Document WO2006/061541 A2 additionally describes a method for manufacturing a decorated glass sheet with a functional coating comprising the following successive steps:
dimensioning of the glass sheet;
screen printing of the enamel-based decorative pattern;
deposition of the functional coating onto the glass sheet by pyrolysis
conducting operations of firing the enamel and depositing the functional coating simultaneously in a pass in a furnace.

Such a process necessarily requires that the glass sheet is dimensioned before any printing of the decorative pattern. This initial cutting operation results in a reduced flexibility of the process. Moreover, the functional coating is deposited by pyrolysis, which excludes the possibility of using low-emissivity or solar shield functional coatings based on metallic silver obtained by magnetron cathodic sputtering.

### 3. OBJECTIVES OF THE INVENTION

In particular, the object of the invention is to remedy, these disadvantages of the prior art.

More specifically, an object of the invention in at least one of its embodiments is to provide a method for manufacturing a decorated glass sheet covered with a functional coating, wherein said method provides greater flexibility.

Another object of the invention in at least one of its embodiments is to implement a method that allows work on glass sheets of large dimension such as PLF or DLF format that are suitable for subsequent customised cutting.

An additional object of the invention in at least one of its embodiments is to provide a method enabling formation of a decorated glass sheet covered with a functional coating that provides low-emissivity or solar protection properties, or is covered with an oxide- or nitride-based protective coating or covered with an electrically conductive coating based on at least one doped oxide, wherein said sheet exhibits a pleasing aesthetic appearance due to the fact that the appearance of the decorative pattern is not modified by the deposit of said functional coating.

### 4. OUTLINE OF THE INVENTION

According to a particular embodiment, the invention relates to a method for manufacturing a decorated glass sheet covered with a functional coating comprising the following successive steps:
application by printing of at least one decorative pattern to at least one portion of a face of the glass sheet;
drying of the printed decorative pattern.

According to the invention such a method also includes the deposition by magnetron cathodic sputtering of the functional coating at least partially covering said decorative pattern.

The general principle of the invention lies in the deposition by magnetron cathodic sputtering of the functional coating on at least one portion of the decorative pattern after the printing and drying of said pattern.

Thus, the invention is based on a completely novel and inventive approach. The inventors have in fact surprisingly determined that it is possible to deposit a functional coating by magnetron cathodic sputtering after simple drying of the printed decorative pattern without there being any damage to said pattern as a result of degassing when placing the cathodic sputtering installation under vacuum, and therefore without any contamination of said installation. Drying is understood to mean a thermal treatment process, in which the conditions in terms of temperature and duration of treatment are lower than those used as part of the firing of said pattern. The inventors have likewise determined, also surprisingly, that although a functional coating obtained by cathodic sputtering has a much smaller thickness than coatings obtained by pyrolysis, there is no problem of any step-like discontinuity created by the difference in levels between the surface of the glass sheet and the surface of the printed decorated pattern, this discontinuity of the functional coating being made apparent by the presence of coronae.

The invention thus enables the provision of a method for manufacturing a decorated glass sheet covered with a functional coating that has much greater flexibility at the logistic level of the glasses produced. In fact, different decorations can be combined on the same glass sheet, and said sheet is transported to a final transformer that will be able to subsequently cut it to customised size and toughen it. In addition, the aesthetic appearance of the decorated glass sheet is retained after deposition of the functional coating.

The term “glass sheet” is understood to relate to a sheet of inorganic glass. The glass can belong to various categories. The glass can be a soda-lime type glass, a boron glass, an aluminosilicate glass, a glass containing one or more additives distributed homogeneously in its bulk such as, for example, at least one inorganic colouring agent, an oxidising compound, a viscosity-regulating agent and/or a fusion-promoting agent. The glass is preferably a soda-lime glass. The glass of the invention can be a float glass, a drawn glass or a patterned glass. It can be clear, extra-clear, sanded and/or frosted. The expression “soda-lime glass” is used in its broad sense here and relates to any glass that contains the following base components (expressed in percentages of the total weight of glass):

| | |
|---|---|
| SiO₂ | 60 to 75% |
| Na₂O | 10 to 20% |
| CaO | 0 to 16% |
| K₂O | 0 to 10% |
| MgO | 0 to 10% |
| Al₂O₃ | 0 to 5% |
| BaO | 0 to 2% |
| BaO + CaO + MgO | 10 to 20% |
| Na₂O + K₂O | 10 to 20% |

It also relates to any glass containing the above base components that can additionally contain one or more additives. Extra-clear glass is understood to be a glass with a composition containing less than 0.06% by weight of total iron, expressed as Fe₂O₃, and preferably less than 0.02% by weight of total iron, expressed as Fe₂O₃. The term “glass sheet” is also understood to refer to a glass sheet with a thickness at least equal to 0.5 mm and at most 20.0 mm, preferably at least equal to 4.0 mm and at most equal to 10.0 mm.

In the present invention decorative pattern is understood to relate to a single pattern or a plurality of patterns that are separate, arranged side by wide or superposed. When there are a plurality of pattern, these can be in the same form or of different forms. The pattern or patterns can be of a simple geometric form (round, quadrilateral, polygons . . . ) or complex geometric form (designs, logo, lettering, label . . . ). The decorative pattern can be single coloured (white, black, blue, red, green . . . ) or multicoloured. Moreover, said decorative pattern can be opaque or transparent. The thickness of the decorative pattern can be less than or equal to 30 μm, preferably less than or equal to 15 μm.

The composition of the print of said decorative pattern is based on enamel, which is incorporated into a ceramic toner, a ceramic ink or a ceramic paste. The term “enamel” is understood to mean a vitreous substance composed in particular of silica, feldspar, kaolin and metal oxides. The drying conditions of the printed decorative pattern depend on the nature of the print composition. The role of the drying operation is to eliminate organic compounds likely to contaminate the magnetron cathodic sputtering installation during the operation of depositing the functional coating as well as degassing during the subsequent firing/toughening phase that will result in deterioration of the functional coating. These compounds correspond to the organic matrix, in which the enamels are incorporated. In the case of ceramic pastes and inks, this matrix is more or less liquid and drying enables the enamel to be hardened and fixed onto the glass. In the case of powdered toners or inks, the matrix is solid and the role of drying is also to harden and fix the enamel onto the glass after its application in order to prevent any dispersion of the powder forming this toner into the magnetron cathodic sputtering installation. The drying conditions will depend on the type of print composition of the chosen decorative pattern (ceramic ink, paste or toner). Thus, a decorative pattern with a print composition based on ceramic paste or ceramic toner requires drying at a temperature at least equal to 500° C., preferably at least equal to 550° C., wherein the duration of this treatment is dependent on the thickness of the glass sheet, to which the print composition based on enamel incorporated into a ceramic toner or a ceramic paste is applied. This drying time lies in a time range of 40 to 90 seconds per millimetre thickness of the glass sheet, and preferably this drying time is equal to 60 seconds per millimetre thickness of the glass sheet. The inventors have surprisingly found that an ink accordingly requires a drying time of at least 320 seconds at a temperature of at least 150° C. The inventors have also determined that drying is achieved when at least 90%, preferably at least 95%, of the organic substances forming the print composition are evaporated, irrespective of the nature of this composition: ceramic toner or ink. This rate of evaporation is measured by a standard thermogravimetric measurement, a technique known to a person skilled in the art, which also allows the temperature necessary to evaporate the necessary quantity of organic substance to be determined precisely.

The drying step also determines the enamel-based print composition of the decorative pattern used: ceramic toner, ceramic ink or ceramic paste. In order to limit the drying time and the drying temperatures used, print compositions containing organic solvents that evaporate at a temperature lower than or equal to 300° C. are preferred. Of these enamel-based print compositions, ceramic inks, more particularly the ceramic inks used by the “Dip Tech” ink jet printer, are preferred. However, the use of enamel-based ink composition containing solvents with high evaporation temperatures is not excluded, wherein these enamels require drying temperatures of at least 500° C., preferably at least 550° C.

According to an advantageous configuration, a cutting to size of the decorated glass sheet is conducted, either directly or not, after the deposition of the functional coating.

Thus, the invention allows glass sheets of large dimensions such as a PLF (full-width sheet) or DLF (half-width sheet) format to be worked.

According to a preferred embodiment, a thermal treatment of the decorated glass sheet is conducted, directly or not, after the deposition of the functional coating, wherein said thermal treatment corresponds to a firing of the enamel-based print composition of the decorative pattern. This firing is to solidify the decorative pattern by fritting or sintering and also enables the removal of any organic compounds remaining after drying. Fritting or sintering is understood to mean a process that causes a system formed from individual particles (or at porous agglomerate) to develop by thermal treatment in the absence of exerted outside pressure or under the effect of such a pressure, so that this development causes a significant (if not complete) reduction of the initial porosity. The firing temperatures of the enamel-based print compositions are generally in the temperature range of 650° C. to 700° C.

According to an advantageous embodiment, the thermal treatment corresponds to a thermal toughening treatment of the decorated glass sheet when said sheet is intended to be a glass to be toughened. Such an embodiment allows the firing of the decorative pattern and the toughening of the glass sheet to be achieved simultaneously. The temperatures necessary to conduct the thermal toughening of the glass sheet are in the order of 700° C. at maximum. These temperatures are preferably in the order of 690° C. at maximum, more preferred in the order of 670° C. at maximum.

According to another embodiment of the method according to the invention, the thermal treatment of the decorated glass sheet corresponds to a thermal bending treatment of said glass sheet. The temperatures necessary to conduct the thermal bending of the glass sheet are at least higher than 605° C. According to an advantageous embodiment, the thermal treatment corresponds to a thermal bending treatment followed by a thermal toughening treatment.

According to an advantageous embodiment the printing of the decorative pattern is conducted by at least one of the printing methods selected from screen printing, laser printing or ink jet printing. Printing methods such as laser printing, ink jet printing are preferred when each glass sheet must be decorated in a different way, in other words when the decorative pattern varies from sheet to sheet. These methods referred to as digital printing allow targets to be included in the design for a subsequent cutting operation without the process becoming complex. Screen printing is advantageously used in the case of a decorative pattern intended to be produced on a large scale.

According to an advantageous embodiment the method of manufacture according to the invention is such that the functional coating is a low-emissivity, solar shield, protective and/or electrically conductive functional coating based on at least one doped oxide. The term “functional coating” is understood to mean any type of coating. The term “coating” in the sense of the present invention is understood to mean that said coating can be formed from a layer of a single material or a plurality of layers each of a different material. The functional coating can thus be a protective coating that has, for example, sufficient durability to withstand transport, an electrically conductive coating based on at least one doped oxide, preferably selected from tin-doped indium oxide, zinc oxide doped by at least one doping element selected from aluminium, gallium or mixture thereof, and/or a low-emissivity or solar shield type of coating. When the functional coating is a low-emissivity coating, said coating comprises a silver-based layer, preferably a single layer of silver. When the functional coating is a solar shield coating, said coating comprises at least one silver-based layer, preferably at least two silver-based layers and/or said solar shield coating comprises at least one layer based on an oxide of at least one element selected from titanium, zirconium, tin or mixed oxides of at least two of these, preferably titanium zirconium mixed oxide and/or a layer based on a nitride of at least one element selected from silicon, aluminium—indicated as example of solar shield functional coating with no silver layer are the products marketed under the name of “Stopsol Phoenix” from AGC—, and/or said functional coating comprises at least one layer based on semi-metals selected from tungsten, chromium or nickel-chromium mixture, wherein said layer based on semi-metals is protected on either side by at least one oxide-based layer, preferably based on titanium oxide, zirconium oxide, tin oxide or titanium zirconium mixed oxide, or based on, nitride, preferably based on at least one element selected from silicon, aluminium. When the low-emissivity or solar shield functional coating comprises a silver-based layer, the silver is present in pure form or alloyed to another metal, wherein the pure form is preferred, and said silver layer is protected on either side by at least one oxide- or nitride-based layer. When the silver is present in alloyed form, the other metal preferably comprises at least palladium and/or gold, palladium being more preferred. When the functional coating is a low-emissivity or solar shield functional coating comprising at least one silver-based layer, said coating also comprises an assembly of dielectric layers arranged on either side of said silver-based layer. The silver layer has a geometric thickness of at least 5.0 nm, preferably at least 9.0 nm. The silver layer has a geometric thickness of 25.0 nm at most, preferably 18.0 nm at most, more preferred 14.0 nm at most. It is most preferred if the silver layer has a thickness equal to 12.5 nm. The low-emissivity or solar shield coating, preferably the solar shield coating, can comprise several silver-based layers, wherein said layers are separated by dielectric layers that render the decorated glass sheet covered with a functional coating according to the invention anti-reflective in a portion of the spectrum of solar radiation, in particular in the domain of visible wavelengths. Indicated as examples of solar shield functional coating are the products marketed by AGC under the name of “Stopray” and as examples of low-emissivity coating are the products marketed under the designation “TopN, TopN+, TopN+T” from the same company.

According to an advantageous embodiment the method of manufacture according to the invention is such that the functional coating is a protective functional coating comprising at least one oxide of an element selected is from titanium, zirconium, vanadium, niobium, tantalum, aluminium, zinc, silicon, tin, bismuth, indium, mixtures of at least two of these or mixed oxides of at least two of these and/or a nitride of an element selected from titanium, zirconium, aluminium, silicon or mixtures of at least two of these or mixed nitrides of at least two of these.

According to a particular mode of the preceding embodiment, the protective coating is a coating based on silicon nitride and/or based on titanium oxide, wherein said titanium oxide is associated with at least one other oxide of high hardness selected from the group consisting of niobium oxide, silicon oxide of chromium oxide, zirconium oxide, and preferably selected from the group consisting of silicon oxide, chromium oxide, zirconium oxide. The respective proportions of titanium oxide and the other oxides can cover a wide range. To ensure that the protective function is accomplished, the additional oxide or oxides must represent at least 5% by weight of the whole and preferably at least 10%. In the case of a mixed oxide, titanium oxide represents at least 50% by weight, preferably at least 55% by weight of the mixed oxide. With respect to the mixed oxides used in addition to titanium oxide, zirconium oxide is particularly preferred because of its very high hardness. It is advantageously present at a rate of 15 to 50% by weight of the protective layer. Besides titanium oxide and the other oxides listed above, the protective layer can also contain additional oxides that are practically inseparable from the preceding oxides. This is the case in particular with lanthanides such as yttrium or hafnium oxide. When these additional oxides are present their content remains relatively limited and does not exceed 8% by weight of the whole and more frequently remains less than 5%.

According to an embodiment the method of manufacture according to the invention is such that the functional coating is a low-emissivity or solar shield coating comprising at least one silver-based layer, wherein said coating also comprises an assembly of dielectric layers arranged on either side of said silver-based layer.

According to an advantageous embodiment the method of manufacture according to the invention is such that the low-emissivity or solar shield functional coating comprises at least one physical protection means. “Physical protection” is understood to mean a protection against mechanical wear, abrasion, scratching . . . . Since the layers obtained by magnetron cathodic sputtering are so-called soft layers, it is necessary to protect them from any physical degradation. Indicated as examples of protection means are a plastic sheet, a magnetron layer of high hardness such as a titanium zirconium mixed oxide layer, a carbon layer, wherein said physical protection means are deposited onto the low-emissivity or solar shield functional coating.

According to a particular embodiment the method of manufacture according to the invention is such that the low-emissivity or solar shield functional coating comprising a silver-based layer also comprises at least one means for chemical protection of said silver layer. “Chemical protection” is understood to mean a protection against any chemical degradation process of the silver (oxidation, diffusion of alkaline ions from the glass sheet, diffusion of silver during the thermal toughening treatment). Examples of these means are given below:
at least one barrier layer, wherein, in relation to the glass sheet, said barrier layer is the first layer forming the low-emissivity or solar shield functional coating. The material forming the barrier layer is selected from titanium oxide, zinc oxide, silicon nitride, silicon oxynitride, silicon oxycarbide, silicon oxycarbonitride, aluminium nitride, aluminium oxynitride, aluminium oxide, wherein this barrier layer is possibly doped or alloyed with tin. The barrier layer has a geometric thickness of at least 3.0 nm, preferably at least 10.0 nm, more preferred at least 30.0 nm, further preferred at least 50.0 nm. The barrier layer has a thickness of 100 nm at most.
at least one sacrificial layer, wherein the sacrificial layer is located on at least one face of the silver-based layer. Sacrificial layer is understood to be a layer that can be wholly or partially oxidised. This layer enables prevention of damage to the silver layer, in particular by oxidation. When it is present, the sacrificial layer comprises at least one compound selected from metals, nitrides, oxides, metal oxides, substoichiometric in oxygen. Preferably, metals, nitrides, oxides substoichiometric metal oxides comprise at least one element selected from Ti, Zr, Hf, V, Nb, Ta, Cr, Mo, W, Mn, Fe, Co, Ni, Cu, Zn, Al. More preferred the sacrificial layer comprises at least Ti, TiOₓ (with x≦2), NiCr. The thickness of the sacrificial layer is at least 0.5 nm. The thickness of the sacrificial layer is at most 6.0 nm. More preferred, the thickness is equal to 2.5 nm. According to a preferred embodiment a sacrificial layer is deposited on the face of the silver-based layer that is most remote in relation to the glass sheet.

According to a particular embodiment the method of manufacture according to the invention is such that the low-emissivity or solar shield functional coating comprising a silver-based layer comprises a barrier layer comprising at least one compound selected from silicon nitride, silicon oxynitride, aluminium nitride, aluminium oxynitride, aluminium oxide, and preferably the barrier layer is made of silicon oxide. Said layer blocking the to diffusion of the silver when the decorated glass sheet covered with said layer is subjected to a thermal toughening treatment.

According to an embodiment the method of manufacture according to the invention is such that a base layer is deposited onto the glass sheet prior to the application of at least one decorative pattern by printing onto at least one portion of a face of the glass sheet. Said base layer comprises at least one compound selected from titanium oxide, zirconium oxide, niobium oxide, zinc oxide, tin oxide, mixed oxides of at least two of these, silicon nitride, silicon oxynitride, silicon oxycarbide, silicon oxycarbonitride, aluminium nitride, aluminium oxynitride, aluminium oxide, wherein this base layer is possibly doped or alloyed with tin. The materials forming the base layer can also contain in the order of 10%, or even 15%, atomic percent, of additional elements such as silicon.

The base layer has a geometric thickness of at least 10.0 nm, preferably at least 30.0 nm, even more preferred at least 50.0 nm. The base layer has a thickness of 100 nm at most. Preferably, the base layer comprises at least one compound selected from silicon nitride, silicon oxynitride, aluminium nitride, aluminum oxynitride, aluminium oxide, and it is more preferred if the base layer is made of silicon oxide. This base layer has a dual role: on the one hand, it acts as barrier against the diffusion through the enamel of silver from the functional layer comprising a silver layer, and, on the other hand, it generally allows a better adhesion of the enamel. In fact, a low-emissivity or solar shield functional coating comprising a silver-based layer pose a problem of silver diffusion through the enamel during the thermal toughening treatment, which causes the glass sheet, and consequently the glass sheet covered with the decorative pattern, to turn yellow or even brown.

According to another embodiment the method of manufacture according to the invention is such that the print composition of the enamel-based decorative pattern contains elements that block the diffusion of the silver when the functional coating is a low-emissivity or solar shield coating comprising a silver-based layer. In particular in the preceding embodiment the enamel advantageously contains zinc oxide in a quantity of 15 to 70% by weight, silicon dioxide in a quantity of 15 to 40% by weight, boron trioxide in a quantity of 5 to 25% by weight and 0.05% to 15 molar percent of sulphur and/or sulphides, preferably zinc sulphide, wherein said sulphides are separated at least partially.

According to an advantageous embodiment, after the steps of applying by printing at least one decorative pattern onto at least one portion of a face of the glass sheet, drying the printed decorative pattern, depositing the functional coating by magnetron cathodic sputtering, the method according to the invention comprises the following additional successive steps: transport to a mason or processor, storage, cutting to size of the glass sheet, toughening of the cut sheets. The term “mason or processor” is understood to mean a person who undertakes at least the steps of storage, cutting to size of the glass sheet, toughening of the cut sheets.

The invention further relates to a decorated glass sheet covered with a functional coating obtained by means of a method of manufacture according to the invention. The invention also relates to the use of a decorated glass sheet covered with the functional coating obtained by means of a method of manufacture in accordance with the invention as a facade element and also as a facade comprising at least one decorated glass sheet covered with a functional coating obtained by means of a method of manufacture in accordance with the invention. However, other uses are possible for this type of decorated glass sheet covered with a functional coating obtained by means of a method of manufacture according to the invention: indicated by way of example are products that enable the reduction of transfers of heat or products for decorative purposes in the form, for example, of shelving elements, elements in cupboards, doors, more particularly in refrigerator or oven doors, refrigerated counters, ceiling lighting, support elements, elements in glass tables, wall lights, partitions, shop windows, glazed parts in vehicles, more particularly cars, etc.

### 5. LIST OF FIGURES

Other features and advantages of the invention will become clearer on reading the following description of a preferred embodiment given by way of a simple, non-restrictive illustrative example and the attached drawings, wherein:

FIG. 1 schematically shows the different steps of a preferred embodiment of the method for manufacturing a decorated glass sheet covered with a functional coating according to the invention comprising, in succession, the steps of applying by printing at least one decorative pattern to at least one portion of a face of the glass sheet (1), drying the printed decorative pattern (2), depositing the functional coating by magnetron cathodic sputtering (3) transporting to a mason or processor (4), storing (5), cutting the glass sheet to size (6), toughening the cut sheets (7).

FIG. 2 shows an example of the structure of a decorated glass sheet covered with a functional coating comprising the glass sheet (1), a decorative pattern (2) and a functional coating (3).

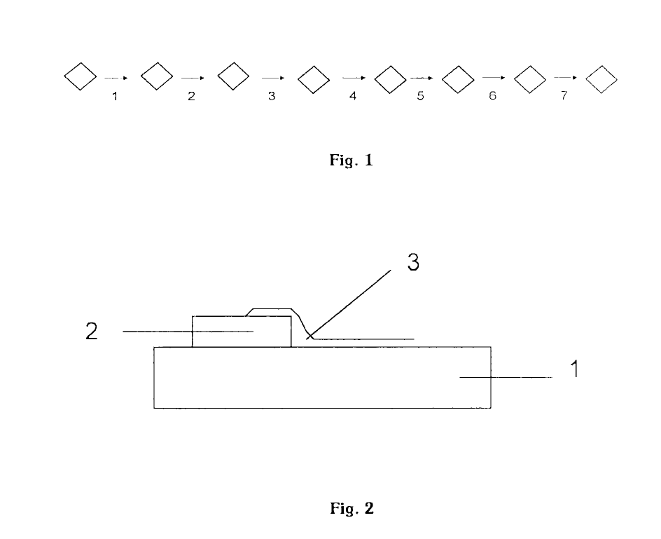

### 6. DESCRIPTION OF AN EXEMPLARY EMBODIMENT OF THE INVENTION

### Example 1

A sample measuring 30×40 cm is cut out of a glass sheet covered with a 30 mm thick layer of SiO₂. It is washed and 6 squares of different colours are printed on this sample using a “Dip tech” ink jet printer. The ink used is a ceramic ink marketed by the supplier of the machine. Once printed, the sample is passed into a dryer. The length of the dryer is 8 m, its speed is 1.5 m/min and its projected temperature is 150° C. The sample is then passed into the coater where a “double silver” type solar shield coating marketed by AGC under the coating name “Stopray” is applied. The sample thus formed is transported to the toughening plant where it is toughened in the usual conditions for toughening a glass covered with a solar shield coating.

### Example 2

A sample measuring 30×30 cm is cut out of a 6 mm thick glass sheet. It is ground and washed. A 5 cm black edge is printed into this sample by screen-printing and this edge ends with an inner frame to the interior of the glass and the logo of a make of car. The paste used is a ceramic paste marketed by Johnson Matthey that contains agents for blocking diffusion of the silver. Once printed, the sample is passed into a dryer. In this case the drying temperature is 550° C. and the drying time is 360 s. The sample is then passed into the coater where a “single silver” type low-emissivity coating marketed by AGC under the coating name “TopN+T” is applied. The sample thus formed is transported to the toughening plant where it is toughened in the usual conditions for toughening a glass covered with a low-emissivity coating.

1. A method for manufacturing a decorated glass sheet covered with a functional coating, the method comprising:
a decorative pattern to portion of a face of a glass sheet, thereby producing a printed decorative pattern,
drying the printed decorative pattern, and
depositing by magnetron cathodic sputtering the functional coating such that it at least partially covers the decorative pattern.

2. The method according to claim 1, a further comprising:
cutting the decorated glass sheet, directly or indirectly, after the depositing.

3. The method according to claim 1,
wherein the decorated glass sheet has a PLF or DLF format.

4. The method according to claim 1, of further comprising: thermally treating the decorated glass sheet, directly or indirectly, after the depositing,
wherein the thermally treating is firing an enamel-based print composition of the decorative pattern.

5. The method according to claim 1,
wherein the printing is at least one printing method selected from the group consisting of a screen printing, a laser printing, and an ink jet printing.

6. The method according to claim 1,
wherein the functional coating is a low-emissivity functional coating, solar shield functional coating, protective functional coating, electrically conductive functional coating, or a combination thereof based on at least one doped oxide.

7. The method according to claim 6,
wherein the functional coating is a protective functional coating comprising:
i) at least one oxide or at least one mixed oxide of an element selected from the group consisting of titanium, zirconium, vanadium, niobium, tantalum, aluminium, zinc, silicon, tin, bismuth, and indium,
ii) at least one nitride or at least one mixed oxide of an element selected from the group consisting of titanium, zirconium, aluminium, and silicon, or
both i) and ii).

8. The method according to claim 7,
wherein the protective coating is a coating based on silicon nitride, titanium oxide, or both silicon nitride and titanium oxide and at least one other oxide of high hardness selected from the group consisting of niobium oxide, silicon oxide, chromium oxide, and zirconium oxide.

9. The method according to claim 6,
wherein the functional coating is a low-emissivity or solar shield functional coating comprising a silver-based layer, and
the functional coating further comprises an assembly of a dielectric layer arranged on either side of the silver-based layer.

10. The method according to claim 9,
wherein the low-emissivity or solar shield functional coating comprises an article for physical protection.

11. The method according to claim 9,
wherein the low-emissivity or solar shield functional coating comprises an article for chemical protection of the silver-based layer.

12. The method according to claim 1, further comprising:
depositing a base layer onto the glass sheet prior to the applying.

13. A decorated glass sheet covered with a functional coating obtained by the method according to claim 1.

14. A facade element, shelving element, cupboard element, door element, more particularly in a refrigerator or oven door, refrigerated counter, ceiling lighting, support element, in a glass table, a wall light, a partition, a shop window, a glazed parts in a vehicle, comprising:
the decorated glass sheet according to claim 13.

15. A facade, comprising: the decorated glass sheet according to claim 13.
